(19) United States
(12) Patent Application Publication
(10) Pub. No.: US 2006/0125384 A1
(43) Pub. Date: Jun. 15, 2006

(54) Organic light emitting element, production method of organic light emitting element, image forming device, and display unit

(76) Inventors: Tsuneharu Tomita, Osaka-shi (JP); Tetsuroh Nakamura, Takaraduka-shi (JP); Ken-ichi Masumoto, Hirakata-shi (JP); Akira Gyotoku, Saga (JP); Takafumi Hamano, Fukuoka (JP); Yuji Tomomura, Fukuoka-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/534,378

(22) PCT Filed: Nov. 10, 2003
(86) PCT No.: PCT/JP03/14276

§ 371 Date: Oct. 13, 2005

(30) Foreign Application Priority Data
Nov. 11, 2002 (JP) 2002-326367

(51) Int. Cl. H01J 1/62; H01J 63/04

(52) U.S. Cl. 313/506

(57) ABSTRACT

With a conventional organic light emitting element, the pixel formation accuracy is controlled by the pattern formation accuracy of an electrode provided on the top surface of an organic layer. Since this electrode pattern must be formed after an organic layer is formed, only the vapor deposition method with low pattern formation accuracy is available. It makes it difficult to form homogenous and fine pixels. In a production method of an organic light emitting element in this invention, after forming a first electrode composed of a transparent electrode and a metal layer, an organic layer coats the transparent electrodes exposed by removing those portions of a metal layer corresponding to pixels, a second electrode is formed on the organic layer. In this method, the pixel formation accuracy depends on only a metal layer removing accuracy. Since the metal layer is removed before the organic layer is formed, the photolithographic technique can be applied to enable homogeneous and fine pixels to be formed.

### TECHNICAL FIELD

The invention relates to an organic light emitting element utilizing the organic EL (electroluminescence), a production method thereof, an image forming device and a display unit which use the element.

### BACKGROUND ART

The conventional organic light emitting element has a configuration as shown in FIG. 9, and it is formed as follows. In addition, FIG. 10 is a schematic plane view of the element under production, wherein an organic layer and a cathode are illustrated only in outline.

A transparent electrode 2 such as ITO is layered on a transparent substrate 1 such as glass by the spattering method or the vapor deposition method (FIG. 10A), and then it is processed by the photolithography and the etching, which become a grid-shaped anode 10 (FIG. 10B). Subsequently, as an organic layer 4, a hole transporting layer made of N,N′-diphenyl-N,N′-bis(3-methylphenyl)-1,1′-diphenyl-4,4′-diamine (hereinafter abbreviated to TPD), a luminescent layer made of 8-quinolinol aluminum complex (hereinafter abbreviated to Alq3), and an electron transporting layer made of 1,3-bis(4-tert-butylphenyl-1,3,4-oxadiazolyl)phenylene (herein after abbreviated to OXD-7) are formed on the grid-shaped anode 10 sequentially by the vapor deposition method (FIG. 10C). And then, on the organic layer 4, a cathode 5 made of a metal such as Al—Li alloy is formed by the vapor deposition method (FIG. 10D).

When a DC voltage or a DC current is applied between the anode 10 and the cathode 5 of the organic light emitting element thus configured, holes are injected from the anode 10 into the luminescent layer through the hole transporting layer and electrons are injected from the cathode 5 to the luminescent layer through the electron transporting layer. In the luminescent layer, the recombination of the hole and the electron is generated. When an excitation concurrently generated is transferred from an excitation state to a ground state, a light having a wavelength equivalent to the energy difference is emitted. Since the wavelength of the emitted light depends on the film structure of the organic layer and the material of the luminescent layer, if the film structure and the material change, a desired luminescent color can be obtained.

The organic light emitting element can provide the compact and high luminance. Hence, there is a try for applying the element to a light source of an image forming device, as disclosed in Japan Laid-open publication Nos. 8-48052 and 9-226171, for example.

On the other hand, the organic light emitting element can be applied to a display unit such as a flat panel display unit, too. In such display unit, the organic light emitting elements are disposed in matrix, and three adjacent organic light emitting elements must emit light in red, green and blue respectively. A production process of the display unit using the organic light emitting element is explained hereinafter according to FIG. 11. Besides, in FIG. 11, the anode 10 placed under the organic layer 4 is illustrated by a broken line.

Three of the grid-shaped anodes 10, which are adjacent each other, are made into a set, and two of the anodes 10 in each set are masked by the shadow mask. The hole transporting layer made of TPD, a red luminescent layer 4A, and the electron transporting layer made of OXD-7 are layered sequentially on the exposed anode 10 (FIG. 11A). Next, whole exposing either one of the two anodes 10 masked when the red luminescent layer 4A was layered, the hole transporting layer, a green luminescent layer 4B, and the electron transporting layer are layered sequentially thereon (FIG. 11B). Subsequently, while exposing only one anode 10 on which no luminescent layer is formed, the hole transporting layer, a blue luminescent layer 4C, and the electron transporting layer are layered thereon (FIG. 11C). And on the respective luminescent layers 4A, 4B, and 4C, grid-shaped cathodes are formed so as to be perpendicular to each anode 10 (FIG. 11D).

On the transparent substrate 1 thus processed, the organic light emitting elements wherein the anodes 10, the organic layers 4, and cathodes 5 are sequentially layered are disposed in matrix. When the DC voltage or the DC current is applied between a desired anode 10 and cathode 5, the organic light emitting element at a position where the anode 10 and the cathode 5 intersect is allowed to emit light. And light in three colors of RGB can be emitted by using adjacent three organic light emitting elements.

### DISCLOSURE OF INVENTION

In the conventional production method of the organic light emitting element as described above, a pixel 6 is an area that an anode 10, an organic layer 4 and a cathode 5 overlap each other, as shown in FIG. 9, FIG. 10E, and FIG. 11D, so that the size of the pixel 6 varies large depending on the position accuracy at the formation of the cathode pattern.

The organic layer 4 has a feature that the luminance characteristic deteriorates due to the moisture and the heat, and the photolithography, the etching, and the like cannot be performed after the organic layer 4 is formed. Because of this, the organic layer 4 and the cathode 5 can be formed by evaporating the materials through the shadow mask (a metal board provided with an opening at a portion corresponding to a position to form the pattern thereon). However, it is hard for the vapor deposition method to control the position accuracy of the pattern formation for the cathode 5 in micron order, and this brings out troubles that a pixel of the organic light emitting element formed by a different vapor deposition lot varies in size, and the luminance has the dispersion.

Additionally, even in case of the organic light emitting element formed in linear or in matrix on the same substrate, it is hard to control the linearity of an end surface of the cathode and the intersecting angle of the cathode 5 and the anode 10 in micron order. This brings out troubles that the pixel formed on each anode varies in size, and the luminance has the dispersion.

When such organic light emitting element is applied to the light source of the image forming device or the display unit, the luminance dispersion as above becomes a serious problem directly causing the lowering of the performance of the device. And when a minute pixel is formed, the affection such as the size dispersion of pixels comes out conspicuously. This causes a factor that makes it hard to produce the image forming device with high resolution and the display unit with high resolution.

The invention is suggested considering the above-mentioned problems, and has objects to provide an organic light emitting element wherein the luminance dispersion is reduced by reducing the dispersion of the size of the pixel, and a method thereof, and concurrently to provide a downsized image forming device and display unit.

To achieve the above objects, the invention applies following means. The organic light emitting element in the invention is produced according to a following method. That is, after forming each film of a transparent electrode and a metal layer sequentially on a transparent substrate, a first electrode composed of the transparent electrode and the metal layer is formed. And by removing the metal layer of an area corresponding to a pixel of the first electrode by the etching, the transparent electrode is exposed. And then, an organic layer is formed so as to coat the exposed transparent electrode, and on the organic layer a second electrode is formed.

According to the above method, the size of the pixel is limited to the area from which the metal layer is removed, with the result that the process after the etching of the metal layer does not require the high position accuracy. That is to say, it is possible to reduce the size dispersion of the pixel of the organic light emitting element formed by the different vapor deposition lot.

Moreover, since the removal of the metal layer is performed based on a resist opening formed by the method having the high position accuracy, such as the photolithography, even the organic light emitting element formed on the different substrate has no size dispersion of the pixel, and a minute pixel can be formed accurately and homogeneously.

The first electrode is formed in grid being separated electrically, and on each electrode a pixel is formed. In this case, even if the second electrode moves from its position or the second electrode is not perpendicular to the first electrode at the formation of the second electrode, the pixel size does not vary as long as the second electrode is placed on the pixel. That is to say, it is possible to lighten the position accuracy necessary for the formation of the second electrode, and to reduce the size dispersion of the pixel formed on the grid-shaped first electrode, and to produce the organic light emitting element having less luminance dispersion.

Besides, when the metal layer is etched, in order to etch the metal layer on the transparent electrode without etching the transparent electrode, the material of the metal layer is preferable to a metal to allow the metal layer to be etched selectively without etching the transparent electrode.

And the organic light emitting element produced by the production method of this invention is provided with the metal layer on the area except the pixel on the transparent electrode, so that the invention can provide an effect that the parasitic resist of the first electrode can be reduced. Since the metal layer can reduce the parasitic resist from the transparent electrode to a nearest point to the pixel, the luminance dispersion caused from the dispersion of the parasitic resist can be reduced, too.

However, for the reason that the organic light emitting element is provided with the metal layer, a stair of which thickness corresponds to that of the metal layer is formed at the pixel edge. Since the organic layer is about 0.1 to 3 μm thick, if the stair is thick more than the thickness of the organic layer, the thickness of the organic layer gets thin at a corner of the stair. There is a possibility that the first electrode and the second electrode short-circuit. To avoid short-circuit of the first electrode and the second electrode, an insulating layer is provided to an upper surface of the metal layer. Otherwise the metal layer may be provided with a portion reducing the thickness toward the pixel edge. The portion of the metal layer thus reducing in thick may be formed by a slanting surface wherein the thickness of the metal layer becomes thinner toward the pixel edge, or by a stepped form that the thickness of the metal layer becomes thinner toward the pixel edge step by step, and the metal layer may be thick not more than the thickness of the organic layer.

And since the organic layer is also layered on the metal layer, the holes are injected from the transparent electrode to the organic layer through the metal layer, whereby it is considered that the organic layer emits the light between the first and second electrodes. The light is blocked by the metal layer, and it is not taken to outside. And it consumes only the power and reduces the luminescence efficiency. Because of this reason, the material of the metal layer is preferable to a metal having a work function smaller than that of the transparent electrode. The potential barrier against the holes is formed between the transparent electrode and organic layer by using the metal having the smaller work function, whereby the holes to be injected from the transparent electrode to the organic layer through the metal layer are reduced. Accordingly, it is possible to improve the luminescence efficiency.

In addition, the invention makes it easy to dispose the organic light emitting elements linearly, and allows the organic light emitting elements to be disposed at very small intervals, so that it is possible to produce a compact linear beam irradiator with no luminance dispersion. The linear beam irradiator can be used as a light source of the image forming device such as the printer, or the like.

Moreover, the invention makes it easy to dispose the organic light emitting elements in a matrix form and at very small intervals, so that the organic light emitting element can be used to the display unit with high resolution in which the luminance has no dispersion.

### BRIEF DESCRIPTION OF DRAWINGS

FIG. 1 is a schematic sectional view of an organic light emitting element of the invention.

FIG. 2 is a schematic plane view showing a production method of an organic light emitting element of the invention.

FIG. 3 is a schematic sectional view of an organic light emitting element provided with an insulating layer of the invention.

FIG. 4 is a schematic sectional view of an organic light emitting element provided with a slanting surface of the invention.

FIG. 5 is a schematic sectional view of an organic light emitting element having a gradually thinned form.

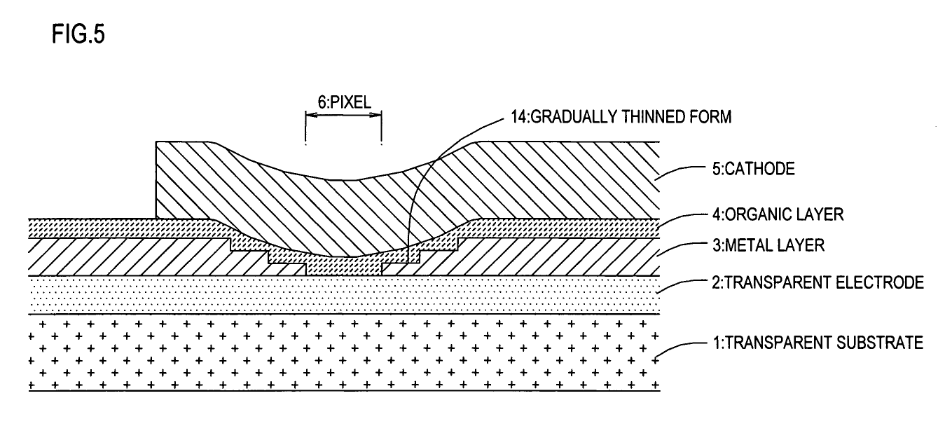

FIG. 6 is a schematic sectional view showing a method of forming the slanting surface.

FIG. 7 is a schematic sectional view showing a method of forming the slanting surface.

FIG. 8 is a schematic plane view showing a production method of an organic light emitting element of the invention.

FIG. 9 is a schematic sectional view of a conventional organic light emitting element.

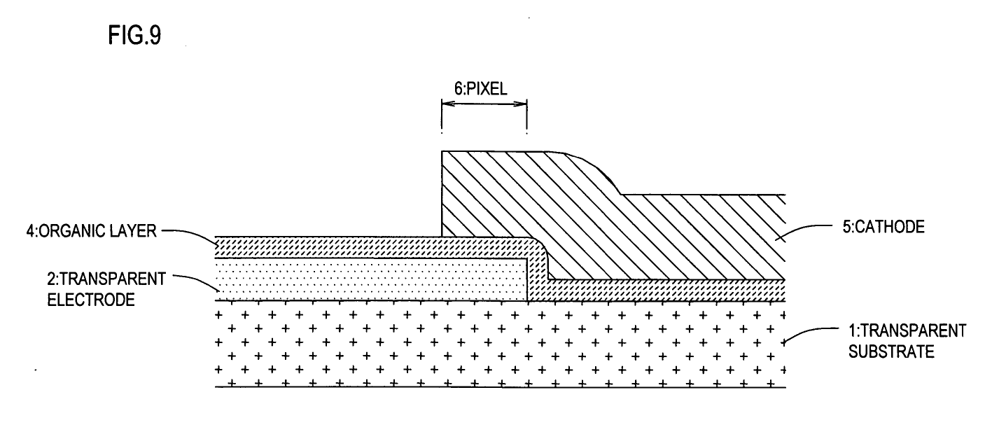

FIG. 10 is a schematic plane view showing a production method of the conventional organic light emitting element.

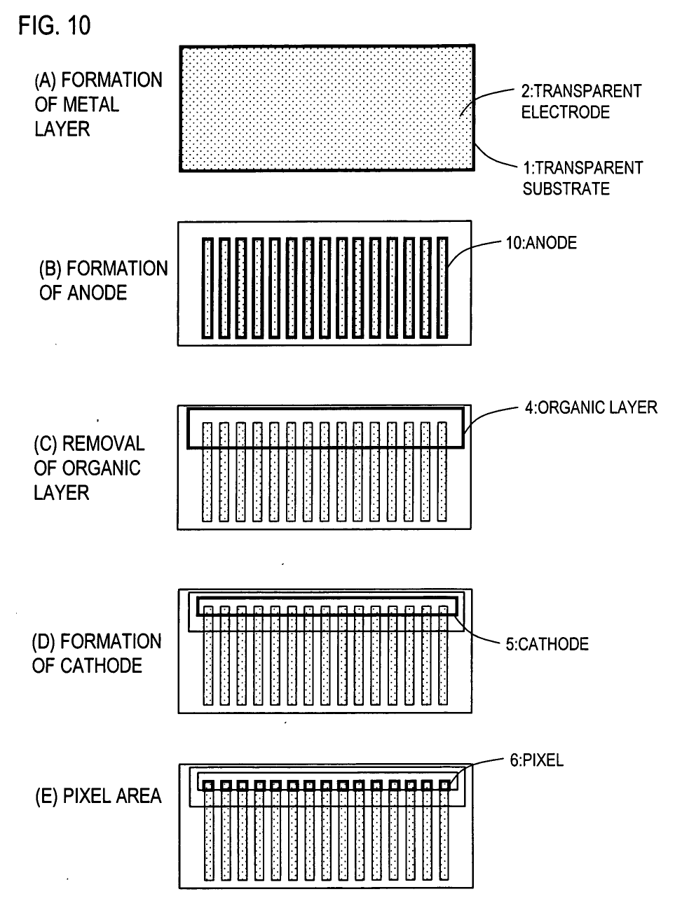

FIG. 11 is a schematic plane view showing a production method of the conventional organic light emitting element.

### BEST MODE FOR CARRYING OUT THE INVENTION

Embodiments of the invention are explained in details hereinafter according to the attached figures.

### EMBODIMENT 1

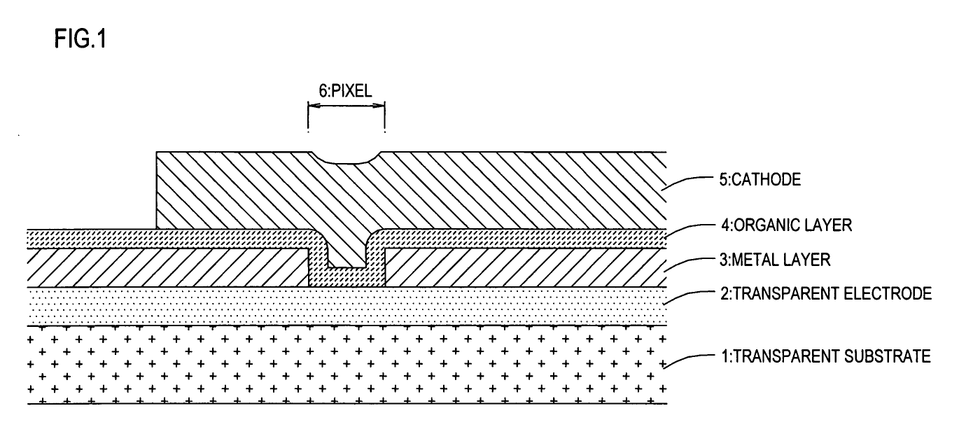

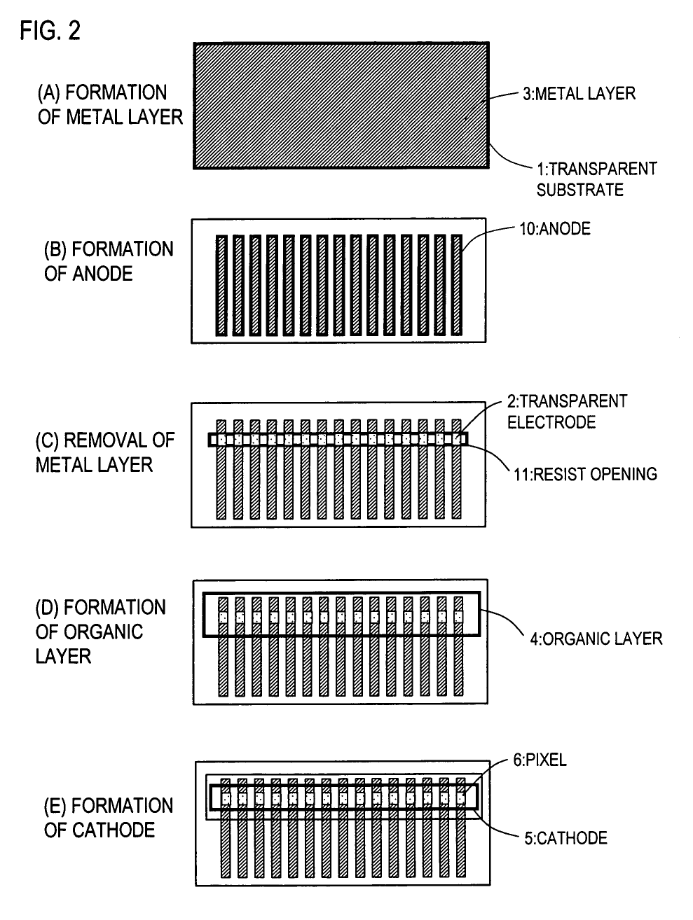

FIG. 1 is a schematic sectional view of an organic light emitting element to which the invention is applied. FIG. 2 is a schematic plane view of the element under production.

According to FIG. 2, a production method of plural light emitting elements disposed in a line is explained hereinafter.

On a transparent substrate 1 such as a glass substrate, a transparent electric conductor such as ITO is layered by the vapor deposition method or the spattering method, which forms a transparent electrode 2. And on the transparent electrode 2, a metal having a resistivity lower than that of the transparent electrode 2, such as Cr, is layered by the vapor deposition method or the spattering method, which forms a metal layer 3 (FIG. 2A).

After a resist is applied to the metal layer 3, the pattern forming of the resist by the photolithography, the etching of the metal layer and the transparent electrode at a resist opening, and the removal of the resist, are rendered. Thereby, an anode 10, which is a first electrode composed of the transparent electrode 2 and the metal layer 3, is formed in grid (FIG. 2B).

Subsequently, after a resist is applied to the substrate on which the anodes 10 are formed in grid, the resist opening 11 is formed in strip on the metal layer within an area corresponding to a pixel of the grid-shaped anode 10. The strip of resist opening 11 is formed so as to intersect orthogonally with the grid-shaped anode 10, and contains areas corresponding to pixels within plural anodes 10.

Based on the resist openings 11, the metal layer within an area corresponding to pixels in the grid-shaped anode 10 is etched, and the transparent electrode 2 is exposed (FIG. 2C). The metal layer is removed in such way, with the result that a size of pixel 6 is limited to an area where the anode 10 and the strip of resist opening 11 overlap each other (an area from which the metal layer is removed). Accordingly, the pixel size cannot change by subsequent processes. In addition, since the anode 10 except for the pixel 6 becomes a two-layer structure formed by the transparent electrode 2 and the metal layer 3, the parasitic resistance of the element can be kept in small. And hereby, it is possible to reduce the dispersion of the luminance caused by the parasitic resistance.

Besides, a material of the metal layer 3 to be formed on the transparent electrode 2 is preferable to a material to etch only the metal layer 3 selectively without etching the transparent electrode 2. For instance, in case where the transparent electrode 2 is ITO and the metal layer is Cr, though ITO is etched by means of an etching solution of water, hydrochloric acid, and ferric chloride (mass ratio, 1:1:0.02), Cr can be selectively etched by means of an etching solution of water, cerium ammonium nitrate, and perchloric acid (mass ratio, 1:0.17:0.05).

After the resist on the substrate is removed, an organic layer 4 is formed on the substrate on which transparent electrode 2 is exposed, in a strip wider than the transparent electrode 2. The organic layer 4 may be formed by the vapor deposition method by layering sequentially a hole transporting layer made of TPD, a luminescent layer made of Alq3, an electron transporting layer made of OXD-7 (FIG. 2D). Besides, in this embodiment, the organic layer 4 is formed in a three-layer structure of the hole transporting layer, the luminescent layer, and the electron transporting layer. However, it is a matter of course that the organic layer may be formed in one of a single-layer structure of the luminescent layer, and a two-layer structure of the hole transporting layer and the luminescent layer or the luminescent layer and the electron transporting layer.

Next, by layering the metal layer of Al—Li alloy on the organic layer 4 (the exposed transparent electrode 2) by the vapor deposition method, a cathode 5 is formed as a second electrode, whereby the organic light emitting element can be formed (FIG. 2E).

As described above, the size of the pixel 6 is limited to an area on which the metal layer 3 is etched, whereby the process following the etching of the metal layer 3 does not require the high position accuracy. Therefore, even if the organic layer 4 and the cathode 5 are formed by the vapor deposition method using the shadow mask instead of the photolithography with the high position accuracy, the pixels do not vary in size. That is to say, even if the position of the cathode 5 is not aligned at the formation of the cathode 5, or even if the cathode 5 is not perpendicular to the anode 10, each pixel does not vary in size as long as the cathode 5 is placed on the pixel 6. Therefore, it is possible to reduce the dispersion of the size of the pixel formed on each grid-shaped electrode.

In addition, since the resist opening 11 is formed by a method with the high position accuracy, such as the photolithography, even if an organic light emitting element is formed on a different substrate, the pixel 6 does not vary in size. Therefore, this makes it possible to form a minute pixel homogeneously with the high accuracy.

On the other hand, according to the above-mentioned configuration, a stair having a thickness equivalent to that of the metal layer 3 is formed at a pixel edge. Since the thickness of the organic layer is about 0.1 to 3 μm, if the thickness of the stair is larger than the thickness of the organic layer 4, the organic layer 4 becomes thin at a corner of the stair, and this brings about a possibility of short-circuiting the anode 10 and the cathode 5. Accordingly, the metal layer 3 at the edge of the pixel 6 is preferable to thinner than that of the organic layer 4 (not more than 3 μm).

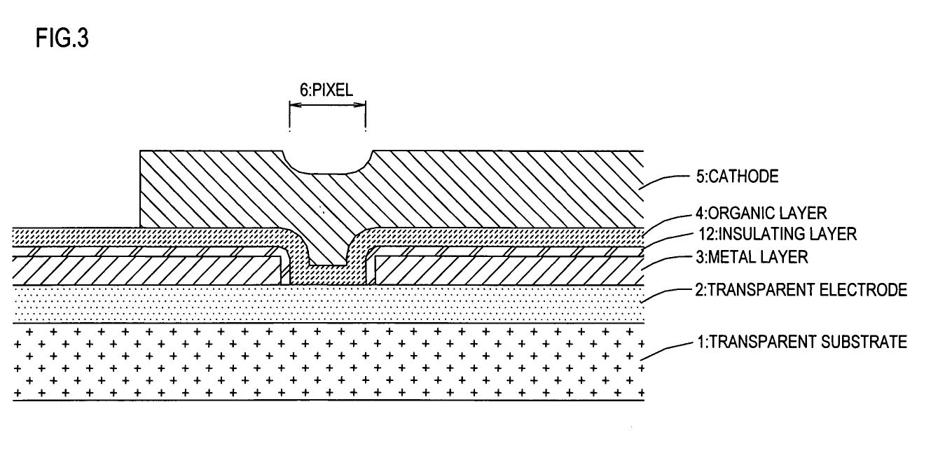

In order to avoid the short circuit of the anode 10 and the cathode 5, an insulating layer 12 may be formed on an upper surface of the metal layer 3, as shown in FIG. 3. The insulating layer 12 is formed by thermally oxidizing the metal layer 3 before forming the organic layer 4. Otherwise, the insulating layer can be formed before forming the organic layer 4, by layering SiO₂, SiON, SiN, and GeO by the CVD method. Or, the insulating layer can be formed by applying the polyimide thereon. Additionally, if the thickness of the insulating layer is 80 to 100 nm, it provides an effect of preventing the short circuit.

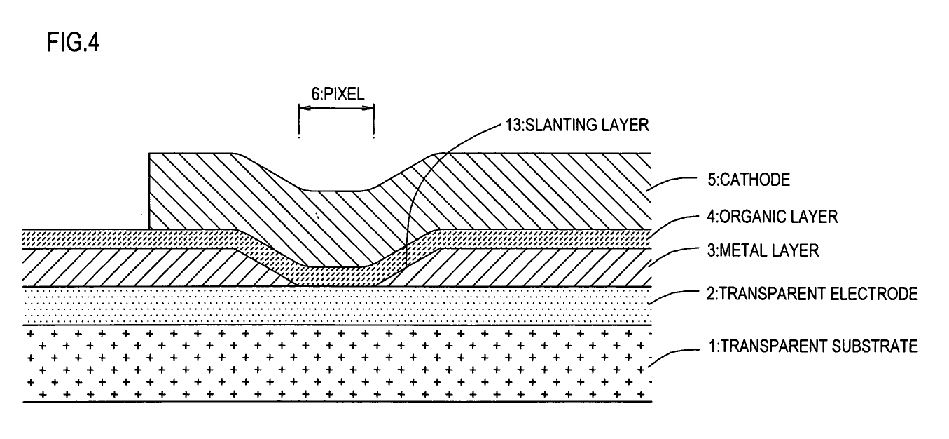

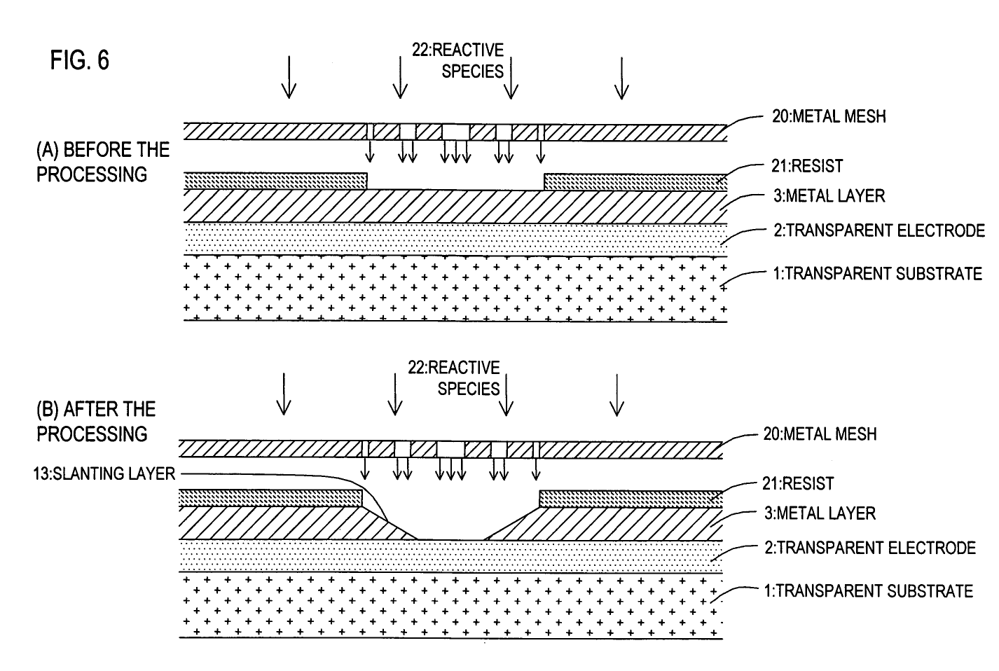

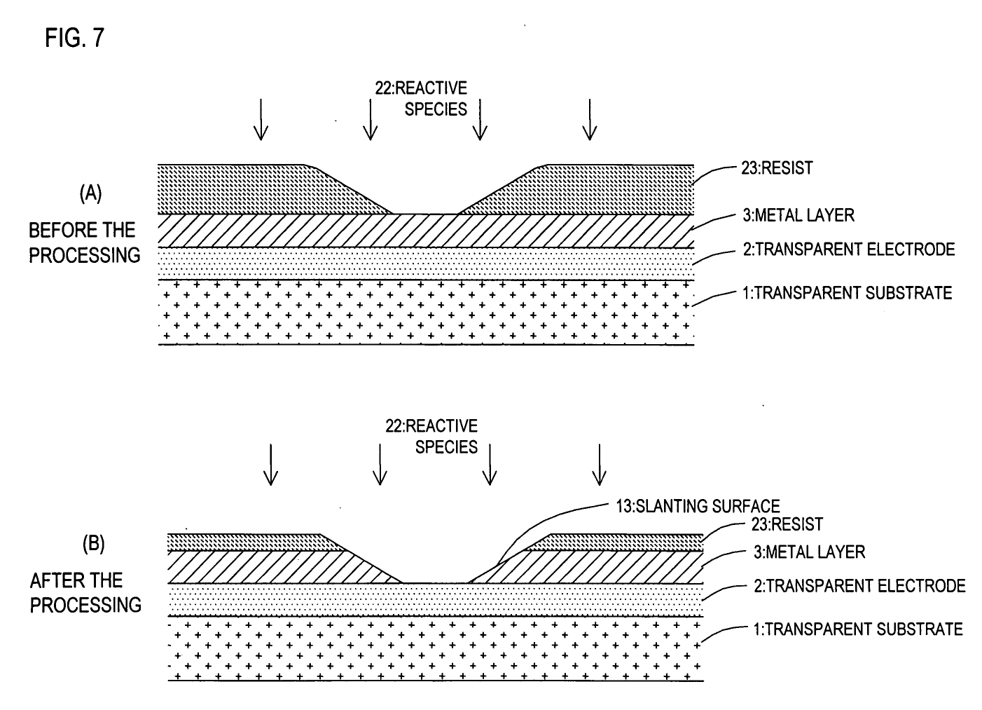

To avoid the short circuit, a slanting surface 13 which become thinner toward the pixel edge may be formed on the pixel edge area of the metal layer 3 as shown in FIG. 4. The slanting surface 13 is formed by the dry-etching method. That is to say, a reactive species 22 is injected into a portion to which the slanting surface is formed through the mask for controlling the depth of the etching, whereby the slanting surface 13 is formed. For instance, the portion to be etched deeply allows the reactive species 22 to be injected in a large amount, while the portion to be etched shallowly allows the reactive species 22 to be injected in a small amount. For this purpose, a metal mesh 20 of which opening is adjusted according to the etching form is provided on a upper surface of the portion to form the slanting surface thereon as shown in FIG. 6, and the etching is performed (the resist 21 is a guard). Otherwise, in order to form a thin resist on the portion to be etched deeply, while to form a thick resist on the portion to be etched shallowly, the resist 23 may be provided on the upper surface of the portion to form the slanting surface thereon as shown in FIG. 7, and then the dry etching is performed. Besides, the slanting surface 13 should have an angle not more than 30 degree in order not to allow the thickness of the metal layer 4 to be thin.

In order to avoid the short circuit, the edge of the pixel on the metal layer 3 may be provided with a stepped form 14 getting thin step by step toward the pixel edge. The stepped form 14 getting thin step by step can be formed by performing plural times of the photolithography and the etching depending on the desired number of steps.

Now, it is considered generally that, since the organic layer 4 is also formed on the metal layer 3, the holes are injected from the transparent electrode 2 to the organic layer 4 through the metal layer 3, and the organic layer 4 emits the light between the transparent electrode 2 and the facing cathode 5. The light is blocked by the metal layer 3, and it cannot be taken out to the outside. And it only consumes the power, and reduces the luminescence efficiency. Therefore, the material of the metal layer 3 is preferable to a metal having a work function smaller than that of the transparent electrode 2. By using the metal having the smaller work function, a potential barrier against the holes is formed between the metal layer 3 and the organic layer 4, and it is possible to reduce the holes injected from the transparent electrode 2 to the organic layer 4 through the metal layer 3, and to improve the luminescence efficiency. For instance, where the transparent electrode 2 is ITO having 4.8 eV, as the work function, it is desirable to use Cu (4.4 eV), Al (4.2 eV), Cr (4.4 eV), and Ag (4.3 eV) as the material of the metal layer 3.

Additionally, since the organic light emitting element formed by the production method of the present invention can be disposed in linear easily as described above, it is possible to configure the linear beam irradiator without luminance dispersion. Since in the linear beam irradiator the light emitting elements can be disposed at minute intervals, it is in a compact size, and can be applied to a light source of the image forming device such as the printer.

### EMBODIMENT 2

The production method of the organic light emitting element of the present invention can be applied to the matrix formation of the elements.

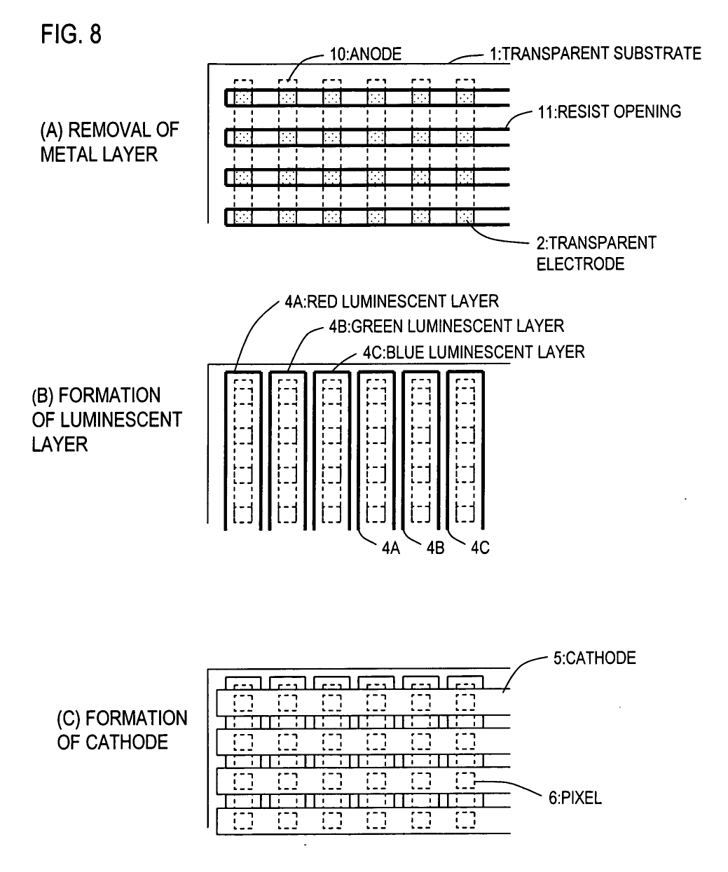

According to FIG. 8, the under-mentioned description refers to the method of producing the organic light emitting elements disposed in the form of matrix. Besides, since the processes from the formation of the grid-shaped anode 10 to the resist application on the substrate are the same as in the embodiment 1, they are omitted here. And the anode below the resist and the organic layer is illustrated by a broken line.

In the first embodiment, a strip-shaped resist opening 11 is formed on the resist. In this embodiment, plural strip-shaped resist openings 11 are formed by the photolithography. The plural strip-shaped resist openings 11 are disposed in parallel at specific intervals. On the grid-shaped anodes 10, the areas corresponding to the pixels are formed in the form of matrix. Under such condition, the metal layer 3 positioned on the areas corresponding to the pixels of the grid-shaped anodes 10 is etched based on the resist opening 11, whereby the transparent electrodes 2 are exposed (FIG. 8A).

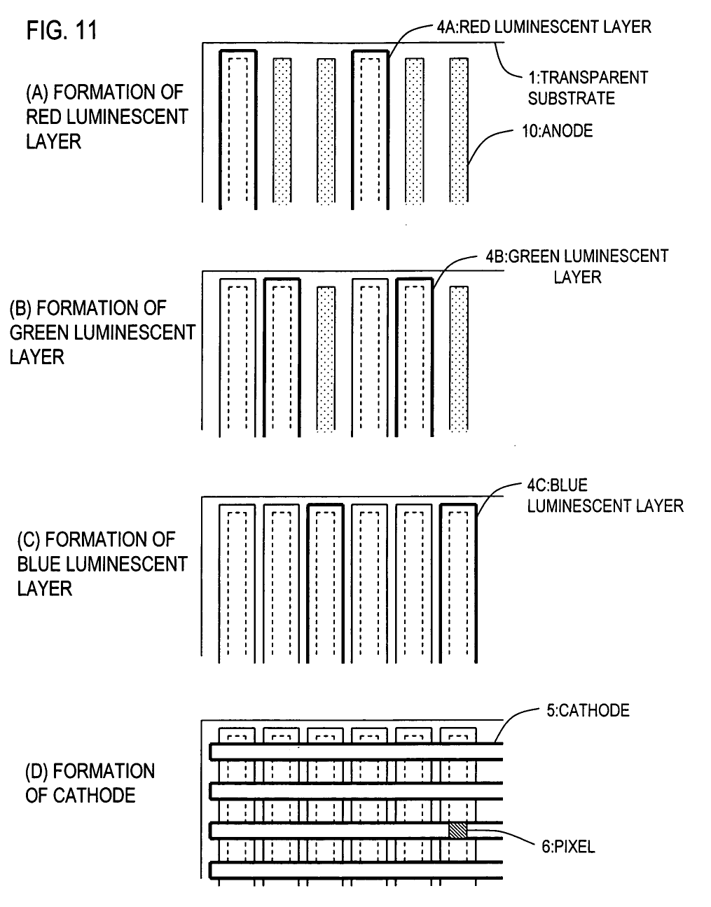

Next, after removing the resist, the organic layer 4 composed of the hole transporting layer, the luminescent layer, and the electron transporting layer is formed on the substrate on which the transparent electrodes 2 are exposed. Besides, since the process of forming the organic layer 4 is the same as a conventional process as shown in FIG. 11, only the state that the organic layer 4 is completed is shown in FIG. 8B.

When the organic layer 4 is formed, 3 of the grid-shaped anodes 10, which are adjacent each other, are made into a set, and 2 of the anodes 10 in each set are masked by the shadow mask. At this time, the anodes 10 to be masked in each set may be any of the anodes, but it is configured in this embodiment that a center anode 10 and a right anode 10 of each set are masked as shown in FIG. 8.

Under the above-mentioned condition, the hole transporting layer made of TPD, a red luminescent layer 4A wherein a red luminous material is injected to Alq3, and the electron transporting layer made of OXD-7 are layered sequentially on the exposed anode 10 through the opening of the shadow mask.

Here, the anodes 10 in each set, on which the red luminescent layer 4A is not layered, are 2. And either one of the two anodes 10 is exposed by the exchange of the shadow mask or the position adjustment. On this exposed anode 10, the hole transporting layer, a green luminescent layer 4B wherein a luminous green material is injected to Alq3, and the electron transporting layer are layered sequentially thereon. The example in FIG. 8 shows that the green luminescent layer 4B is layered on the center anode 10 of each set.

In conclusion, at the time of exposing only the anode 10 on which the luminescent layer is not formed by the exchange of the shadow mask or the position adjustment, namely, when only the right side anode 10 of each set is exposed in this embodiment, the hole transporting layer, a blue luminescent layer 4C wherein a blue luminous material is injected to Alq3, and the electron transporting layer are layered thereon sequentially.

By forming the organic layer 4 as above, it is possible to form each red, green and blue luminescent layer on the grid-shaped anodes 10 cyclically (FIG. 8B).

Besides, the above-mentioned production method of the organic light emitting element is configured so as to form the hole transporting layer and the electron transporting layer only on the portion to form each luminescent layer thereon. However, the hole transporting layer and the electron transporting layer may be formed over the whole substrate.

In the above explanation, it is configured that one color of the luminescent layer is formed on one anode 10, but the configuration is not limited to this. For instance, it may be configured so that one color of the luminescent layer is formed on the exposed portion of the transparent electrode 2 formed by the same striped shaped resist opening (the area corresponding to the pixel), namely, the production method of the organic light emitting element can employ another configuration that the strip-shaped luminescent layers are formed so as to be perpendicular to each anode 10.

On each of the luminescent layers 4A, 4B, and 4C configured as above, the grid-shaped cathode 5 is formed so as to be perpendicular to each anode 10, whereby the organic light emitting elements can be formed in the form of matrix (FIG. 8C).

The organic light emitting elements thus configured can form each pixel 6 accurately in the same way as described in the first embodiment, with the result that it is possible to provide a display unit having a homogeneous luminance without the dispersion. Additionally, the pixel 6, even if it is minute, can be formed accurately and homogeneously, so that it is possible to produce a display unit with the high-resolution.

Moreover, needless to say, the material of the metal layer 3, the structure of the edge of the pixel 6 of the metal layer 3, and the configuration providing on the upper surface of the metal layer 3 with the insulating layer; those are described in the first embodiment, can be applied to this embodiment.

Besides, the transparent substrate 1 to be used to the organic light emitting element of the present invention is not limited in particular, as long as it has a mechanical and thermal intensity and be transparent. For instance, in addition to the glass substrate, there can be use of polyethyleneterephthalate, polycarbonate, polymethylmethacrylate, polyethersulfone, polyvinyl fluoride, polypropylene, polyethylene, polyacrylate, amorphous polyolefin, fluororesin, and the like; those materials with the high transparency for a visible light region. And the substrate may be a flexible substrate that one of those materials is formed to a film.

And the transparent electrode 2 may have the light transparency and include a dopant so as to function the holes as a carrier. For instance, in addition to ITO, there can use be use of ATO (SnO₂ doped with Sb), AZO (ZnO doped with Al), and the like.

Except for the respective red, green, and blue luminescent layers used to produce the display unit, the luminescent layer should be made of a fluorescent material that has a fluorescent characteristic in the visible region and is provided with an excellent film forming performance. There can be used of, in addition to Alq3, Be-benzoquinolinol(BeBq2), benzoxazole compounds of 2,5-bis(5,7-di-t-pentyl-2-benzoxazolyl)-1,3,4-thiaziazole, 4,4′bis(5,7-pentyl-2-benzoxazolyl)stilbene, 4,4′-bis[5,7-di-(2-methyl-2-butyl)-2-benzoxazolyl]stilbene, 2,5-bis(5,7-di-t-pentyl-2-benzosazolyl)thiophene, 2,5-bis([5-α,α-dimethylbenzyl]-2-benzoxazolyl)thiophene, 2,5-bis[5,7-di-(2-mehyl-2-butyl)-2-benzoxazolyl]-3,4-diphenylthiophene, 2,5-bis(5-methyl-2-benzoxazolyl)thiophene, 4,4′-bis(2-benzoxazolyl)biphenyl, 5-methyl-2-[2-[4-(5-methyl-2-benzoxasazolyl)phenyl]vinyl]benzoxazolyl, 2-[2-(4-chlorophenyl)vinyl]naphth[1,2-d]oxazol, and the like, benzothiazole compounds of 2,2′-(p-phenylenedivinylene)-bisbenzothiazole and the like, fluorescent brightening agent of benzimidazole compounds of 2-[2-[4-(2-benzimidazolyl)phenyl]vinyl]benzoimidazole, 2-[2-(4-carboxyphenyl)vinyl]benzoimidazole, or the like, 8-hydroxyquinolin metal complex of tris(8-quinolinol)aluminum, bis(8-quinolinol)magnesium, bis(benzo[f]-8-quinolinol)zinc, bis(2-methyl-8-quinolinolate)alminium oxide, tris(8-quinolinol)indium, tris(5-methyl-8-quinolinol)aluminium, 8-quinolinol lithium, tris(5-chloro-8-quinolinol)gallium, bis(5-chloro-8-quinolinol)calcium, poly[zinc-bis(8-hydroxy-5-quinolinolyl)methane], and the like, or metalchelate oxynoid compounds of dilithiumepindrizion or the like, styrylbenzene compounds of 1,4-bis(2-methylstyryl)benzene, 1,4(3-methylstyryl)benzene, 1,4-bis(4-methylstyryl)benzene, distyryl benzene, 1-4-bis(2-ethylstyryl)benzene, 1,4-bis(3-ethylstyryl)benzene, 1,4-bis(2-methylstyryl)2-methylbenzene and the like, distylpyrazine derivative of 2,5-bis(4-methylstyryl)pyrazine, 2,5-bis(4-ethylstyryl)pyrazine, 2,5-bis[2-(1-naphthyl)vinyl]pyrazine, 2,5-bis(4-methoxystyryl)pyrazine, 2,5-bis[2-(4-biphenyl)vinyl]pyrazine, 2,5-bis[2-(1-pyrenyl)vinyl]pyrazine and the like, naphthalimide derivative, perylene derivative, oxadiazole derivative, aldazine derivative, cyclopenthadiene derivative, styrylamine derivative, coumarin derivative, aromatic dimethylidine derivative or the like. Further, there can be use of anthracene, salicylate, pyrene, chronene, and the like.

The hole transporting layer is preferable to that with the high hole mobility, the transparency and the excellent film forming performance. In addition to TPD, there can be use of polyfiline compounds of porfin, tetraphenylporfin copper, phthalocyanine, copper phthalocyanine, titanium phthalocyanine oxide and the like, third class aromatic amines of 1,1-bis{4-(di-P-tolylamino)phenyl}cyclohexane, 4,4′,4″-trimethyltriphenylamine, N,N,N′,N′-tetrakis(P-tolyl)-P-phenylenediamine, 1-(N,N-di-P-torylamino)naphthalene, 4,4′-bis(dimethylamino)-2-2′-dimethyltriphenylmethane, N,N,N′,N′-tetraphenyl-4,4′-diaminobiphenyl, N,N,-diphenyl-N,N′-di-m-tolyl-4,4′-diaminobiphenyl, N-phenylcarbazole and the like, stilbene compounds of 4-di-P-tolylaminostilbene, 4-(di-P-tolylamino)-4′-[4-(di-P-torylamino)styryl]stilbene and the like, organic materials of triazole derivative, oxaziazole derivative, imidazole derivative, polyallylalkane derivative, pyrazoline derivative, pyrazolone derivative, phenylenediamine derivative, anilamine derivative, amino substituted chalcone derivative, oxazole derivative, styrylanthracene derivative, fluorenone derivative, hydrazone derivative, silazane derivative, polysilane-aniline polymer, high molecular oligomer, styrylamine compounds, aromatic dimethylidine compounds, poly3-methylthiophene and the like. Further, there also can be use of a hole transporting layer of polymer dispersing species in which an organic material for a low molecular hole transporting layer is dispersed in polymer of polycarbonate and the like.

As the electron transporting layer, there can be use of oxadiazole derivatives such as OXD-7, anthraquinomethane derivative, diphenylquinone derivative, and the like.

And as the cathode 5, there can be use of a metal such as Al, In, Mg, Ti, or the like, or there can be use of a metal or an alloy having a low work function, such as an Al—Li alloy, an Al—Sr alloy, an Al—Ba alloy and the like.

### INDUSTRIAL APPLICABILITY

The invention can extraordinarily reduce the dispersion of the luminance of the organic light emitting element, and provide an effect that minute pixels can be formed accurately and homogeneously. And the invention is of much help to the improvement for the performance of the organic light emitting element, the light source of the image forming apparatus with high resolution, and the display unit with high resolution.

1. A production method of an organic light emitting element comprising steps of:
forming each layer of a transparent electrode and a metal layer sequentially on a transparent substrate;
forming a first electrode composed of the transparent electrode and the metal layer;
removing the metal layer of an area corresponding to a pixel of the first electrode to expose the transparent electrode;
forming an organic layer to coat the exposed transparent electrode; and
forming a second electrode on the organic layer.

2. The production method of an organic light emitting element as defined in claim 1, wherein the metal layer is formed of a metal that can be etched selectively instead of the transparent electrode.

3. The production method of an organic light emitting element as defined in claim 1, wherein the metal layer is formed of a metal having a work function smaller than a work function of the material of the transparent electrode.

4. The production method of an organic light emitting element as defined in claim 1, further comprising a step of forming an insulating layer on an upper surface of the metal layer.

5. The production method of an organic light emitting element as defined in claim 1, wherein the step of removing the metal layer further comprises a step of forming the metal layer to be not more than 3 μm thick at the pixel edge.

6. The production method of an organic light emitting element as defined in claim 1, wherein the step of removing the metal layer further comprises steps of providing the metal layer with a portion reducing in thickness toward the pixel edge, and forming at the pixel edge a stair of the metal layer on the transparent electrode so as to have a thickness not more than that of the organic layer.

7. The production method of an organic light emitting element as defined in claim 6, wherein the portion thus reducing is a slanting surface having an angle of 30 or less degrees toward the pixel edge.

8. The production method of an organic light emitting element as defined in claim 6, wherein the portion thus reducing is a stepped form that the thickness reduces gradually toward the pixel edge.

9. The production method of an organic light emitting element as defined in claim 1, wherein the first electrode is a grid-shaped electrode separated electrically, and the step of removing the metal layer further comprises a step of removing the metal layer in a form of strip so as to cross the grid-shaped electrode.

10. An organic light emitting element comprising:
a transparent electrode formed on a transparent substrate;
a metal layer formed removing an area corresponding to a pixel on the transparent electrode;
an organic layer coating the area corresponding to the pixel; and
a second layer formed on the organic layer.

11. The organic light emitting element as defined in claim 10, wherein an insulating layer is formed on the upper surface of the metal layer.

12. The organic light emitting element as defined in claim 10, wherein the metal layer is provided with a portion reducing in thickness toward the pixel edge, and a stair of the metal layer on the transparent electrode is formed at the pixel edge so as to have a thickness not more than that of the organic layer.

13. The organic light emitting element as defined in claim 12, wherein the portion thus reducing is a slanting surface having an angle of 30 or less degrees toward the pixel edge.

14. The organic light emitting element as defined in claim 12, wherein the portion thus reducing is a stepped form that the thickness reduces gradually toward the pixel edge.

15. The organic light emitting element as defined in claim 10, wherein the transparent electrode is a grid-shaped electrode separated electrically.

16. An image forming device using the light emitting element defined in claim 15 as a light source thereof.

17. A display unit using the light emitting element defined in claim 15.

18. The production method of an organic light emitting element as defined in claim 2, wherein the first electrode is a grid-shaped electrode separated electrically, and the step of removing the metal layer further comprises a step of removing the metal layer in a form of strip so as to cross the grid-shaped electrode.

19. The production method of an organic light emitting element as defined in claim 3, wherein the first electrode is a grid-shaped electrode separated electrically, and the step of removing the metal layer further comprises a step of removing the metal layer in a form of strip so as to cross the grid-shaped electrode.

20. The production method of an organic light emitting element as defined in claim 4, wherein the first electrode is a grid-shaped electrode separated electrically, and the step of removing the metal layer further comprises a step of removing the metal layer in a form of strip so as to cross the grid-shaped electrode.
